(19) United States
(12) Patent Application Publication
(10) Pub. No.: US 2025/0233321 A1
(43) Pub. Date: Jul. 17, 2025

(54) ANTENNA APPARATUS, COMMUNICATION APPARATUS, AND IMAGE CAPTURING SYSTEM

(71) Applicant: CANON KABUSHIKI KAISHA, Tokyo (JP)

(72) Inventors: YASUSHI KOYAMA, Kanagawa (JP); TAKEAKI ITSUJI, Kanagawa (JP); YUKI KITAZAWA, Kanagawa (JP); TATSUYA MURAO, Kanagawa (JP); KOJI YUKIMASA, Kanagawa (JP); TAKAHIRO SATO, Kanagawa (JP)

(21) Appl. No.: 18/854,907

(22) PCT Filed: Apr. 13, 2023
(86) PCT No.: PCT/JP2023/014967

§ 371 Date: Oct. 7, 2024

(30) Foreign Application Priority Data
Apr. 15, 2022 (JP) 2022-067824

(51) Int. Cl. H01Q 21/06; H01Q 1/22; H01Q 1/24

(52) U.S. Cl. CPC H01Q 21/065; H01Q 1/2283; H01Q 1/24

(57) ABSTRACT

An antenna apparatus comprises: a first substrate including an antenna array in which a plurality of active antennas each including an antenna and a semiconductor structure configured to generate or detect an electromagnetic wave are provided, and a wiring electrically connected to the plurality of active antennas; and a second substrate stacked on the first substrate and including a control circuit of the antenna array, wherein the first substrate and the second substrate are bonded at a bonding surface, the control circuit is electrically connected to the antenna array via the wiring, and the control circuit of the second substrate controls oscillations of the plurality of active antennas of the first substrate.

### CROSS REFERENCE TO RELATED APPLICATIONS

This application is a national phase of PCT Application No. PCT/JP2023/014967, filed Apr. 13, 2023, which in turn claims benefit of Japanese Patent Application No. 2022-067824 filed Apr. 15, 2022, the contents of each of which is incorporated by reference herein.

### BACKGROUND OF THE INVENTION

### Field of the Invention

The present invention relates to an antenna apparatus, a communication apparatus, and an image capturing system.

### Background Art

The development of a semiconductor device that outputs or detects an electromagnetic wave such as a terahertz wave has been accelerated because of the frequency band used by the next generation communication standard 6G. An active antenna formed by integrating a Resonant Tunneling Diode (RTD) and an antenna is expected as a high frequency element that operates at room temperature in a frequency domain around 1 THz. Japanese Patent No. 6373010 discloses an active antenna array of a terahertz wave using an RTD. A material such as InGaAs (indium gallium arsenide) having high electron mobility is used for such high frequency element, and the high frequency element is formed on a semiconductor substrate such as an InP (indium phosphide) substrate. On the other hand, the control circuit of the high frequency element is formed on a semiconductor substrate using a semiconductor material such as Si (silicon).

### SUMMARY OF INVENTION

If a substrate on which a high frequency element is formed and a substrate on which a control circuit is formed are different types of substrates, it is necessary to individually manufacture the substrates. In this case, depending on a method of connecting the substrates on which the high frequency element and the control circuit are formed, respectively, high-speed signal control may be impossible since a signal delay or signal loss occurs due to inductance caused by a wiring length. Furthermore, depending on the connection, the degree of freedom of control of an antenna array may degrade. That is, in an antenna apparatus including a substrate on which a high frequency element is formed and a substrate on which a control circuit is formed, connection between the substrates has not been examined in detail.

The present invention provides a preferable antenna apparatus including a plurality of substrates.

To achieve the above object, an antenna apparatus according to the present invention comprises: a first substrate including an antenna array in which a plurality of active antennas each including an antenna and a semiconductor structure configured to generate or detect an electromagnetic wave are provided, and a wiring electrically connected to the plurality of active antennas; and a second substrate stacked on the first substrate and including a control circuit of the antenna array, wherein the first substrate and the second substrate are bonded at a bonding surface, the control circuit is electrically connected to the antenna array via the wiring, and the control circuit of the second substrate controls oscillations of the plurality of active antennas of the first substrate.

According to the present invention, it is possible to provide a preferable antenna apparatus including a plurality of substrates.

Further features of the present invention will become apparent from the following description of exemplary embodiments (with reference to the attached drawings).

### BRIEF DESCRIPTION OF DRAWINGS

FIG. 1A is a block diagram showing an antenna apparatus 10.

FIG. 1B is a schematic top view showing a first substrate 151 of the antenna apparatus 10.

FIG. 1C is a schematic top view showing a second substrate 152 of the antenna apparatus 10.

FIG. 1D is a schematic top view showing the second substrate 152 of the antenna apparatus 10.

FIG. 2A is a top view of the antenna apparatus according to the first embodiment.

FIG. 2B is a sectional view of the antenna apparatus taken along a line A-A′ according to the first embodiment.

FIG. 2C is a sectional view of the antenna apparatus taken along a line B-B′ according to the first embodiment.

FIG. 2D is a sectional view of the antenna apparatus taken along a line C-C′ according to the first embodiment.

FIG. 3A is a top view of an antenna apparatus according to the second embodiment.

FIG. 3B is a sectional view of the antenna apparatus taken along a line A-A′ according to the second embodiment.

FIG. 3C is a sectional view of the antenna apparatus taken along a line B-B′ according to the second embodiment.

FIG. 3D is a sectional view of the antenna apparatus taken along a line C-C′ according to the second embodiment.

FIG. 4A is a top view of an antenna apparatus according to the third embodiment.

FIG. 4B is a sectional view of the antenna apparatus taken along a line A-A′ according to the third embodiment.

FIG. 4C is a sectional view of the antenna apparatus taken along a line B-B′ according to the third embodiment.

FIG. 4D is a sectional view of the antenna apparatus taken along a line C-C′ according to the third embodiment.

FIG. 5A is a top view of an antenna apparatus according to the fourth embodiment.

FIG. 5B is a sectional view of the antenna apparatus taken along a line A-A′ according to the fourth embodiment.

FIG. 5C is a sectional view of the antenna apparatus taken along a line B-B′ according to the fourth embodiment.

FIG. 5D is a sectional view of the antenna apparatus taken along a line C-C′ according to the fourth embodiment.

FIG. 6A is a view showing an example of the arrangement of a camera system using an antenna apparatus.

FIG. 6B is a view showing an example of the arrangement of a communication system using an antenna apparatus.

### DESCRIPTION OF EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

In the following description, a case in which an antenna apparatus is used as a reception apparatus that detects a terahertz wave will be described but the antenna apparatus can also be used as a transmission apparatus that emits a terahertz wave. A terahertz wave indicates an electromagnetic wave within a frequency range of 10 GHz (inclusive) to 100 THz (inclusive), for example, a frequency range of 30 GHz (inclusive) to 30 THz (inclusive).

### First Embodiment

### (Block Diagram of Stack)

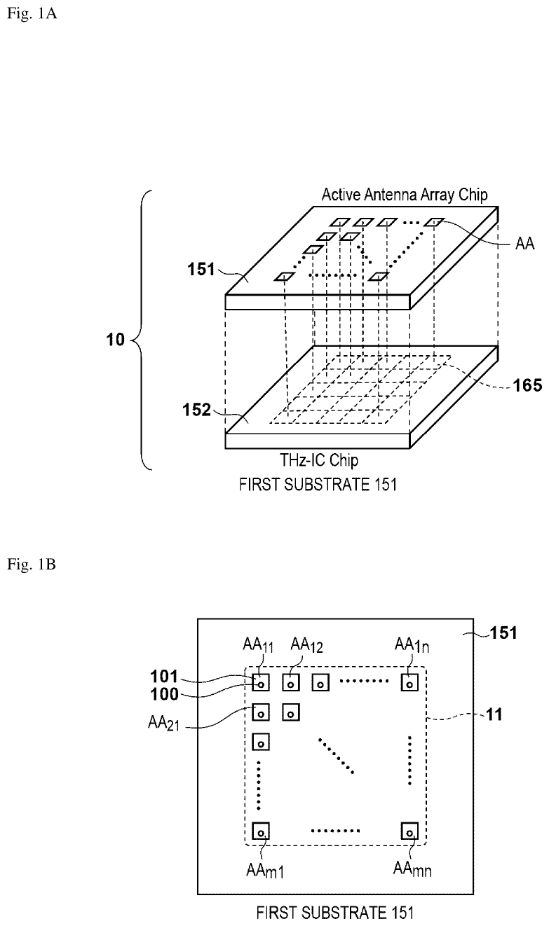

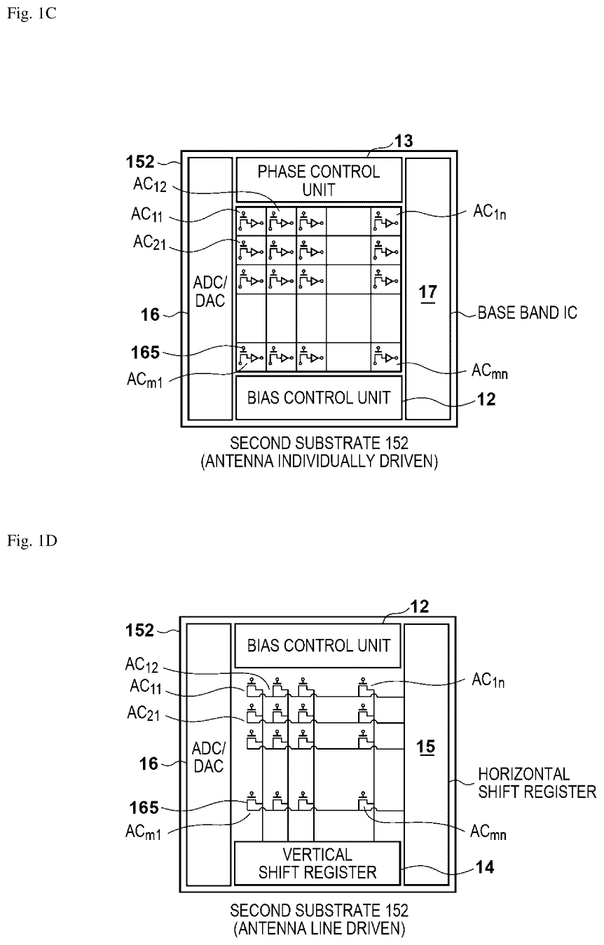

The arrangement of an antenna apparatus 10 according to this embodiment will be described with reference to FIGS. 1A to 1D. FIG. 1A is a block diagram for explaining the chip arrangement of the antenna apparatus 10. FIG. 1B is a schematic top view of a first substrate 151 forming the apparatus 10 when viewed from above. FIGS. 1C and 1D are examples of a schematic top view of a second substrate 152 forming the antenna apparatus 10 when viewed from above.

Referring to FIG. 1A, the antenna apparatus 10 includes the first substrate 151 on which an active antenna array 11 with n active antennas AA₁ to AAₙ arrayed is integrated, and the second substrate 152 including a control circuit for individually controlling the active antennas.

Each of active antennas AA₁₁ to AAₘₙ of the active antenna array 11 of the first substrate 151 includes a semiconductor structure as a semiconductor layer 100 (compound semiconductor layer) for transmitting/receiving a terahertz wave, and a conductor layer 101 in which a wiring is formed. The conductor layer 101 will also be referred to as an antenna wiring layer hereinafter. Therefore, as shown in FIG. 1A, the active antenna array 11 is an antenna array in which m antennas in the vertical direction and n antennas in the horizontal direction (m is equal to or more than 2, n is equal to or more than 2) are arranged in an m×n matrix.

The second substrate 152 includes a control unit (control circuit) 165 for individually controlling the active antennas AA₁₁ to AAₘₙ. The control circuit 165 includes a plurality of control elements AC₁₁ to ACₘₙ. In this embodiment, the control elements AC₁₁ to ACₘₙ are connected to the active antennas AA₁₁ to AAₘₙ in one-to-one correspondence, and are arranged in a matrix, similar to the active antennas AA₁₁ to AAₘₙ. The control elements AC₁₁ to ACₘₙ of the second substrate 152 may be arranged in regions immediately below the corresponding antennas AA₁₁ to AAₘₙ, respectively. In this case, the wiring length between a corresponding antenna ANₘₙ and the control element ACₘₙ is shortest, and the lengths of wirings that couple the respective antennas to the control unit are substantially equal to each other, and it is thus possible to reduce wiring inductance. For example, as shown in FIG. 1C, the second substrate 152 includes a bias control unit 12, a phase control unit 13, a baseband integrated circuit (IC) 17, and an analog-to-digital converter (ADC)/digital-to-analog converter (DAC) 16, and is connected to the control circuit 165 arranged at the center of the second substrate 152. The control circuit 165 includes an electronic integrated circuit of an ON/OFF switch of each antenna, a bias signal control transistor to the semiconductor layer 100, a transistor for phase and output control of each antenna, and the like.

As in a line driving circuit shown in FIG. 1D, the second substrate 152 may include a bias control unit 12, a vertical shift register 14, a horizontal shift register 15, and an ADC/DAC 16, and may be connected to the control circuit 165 arranged at the center of the second substrate 152. In this case, the control circuit 165 includes a semiconductor structure as an electronic integrated circuit of a switch that switches a matrix to be controlled by a signal from the shift register, a bias signal control transistor to the semiconductor layer 100, a transistor for phase and output control of each antenna, and the like. If the active antenna is used as a receiver, a preamplifier or a low-noise amplifier may be provided in the control circuit 165. The control circuit 165 is a transistor-based electronic integrated circuit, and a Complementary Metal Oxide Semiconductor (CMOS) at 90 nm or more and a Fin Field-Effect Transistor (FinFET) at 10 nm or more can optionally be used for a silicon (Si) device. An electronic integrated circuit, as a compound semiconductor device operating in a terahertz band, based on transistors of a silicon germanium (SiGe)—BiCMOS, SiGe-Heterojunction Bipolar Transistor (HBT), indium gallium arsenide (InGaAs)/indium phosphide (InP)-High Electron Mobility Transistor (HEMT), InGaAs/InP-HBT, and gallium nitride (GaN)-HEMT can be used. The BiCMOS is a semiconductor circuit obtained by combining a bipolar circuit and a CMOS circuit. Note that the following embodiments will describe a case in which an Si-MOSFET is used as a transistor but the scope of the present invention is not limited to this.

### (3×3 Active Antenna Array)

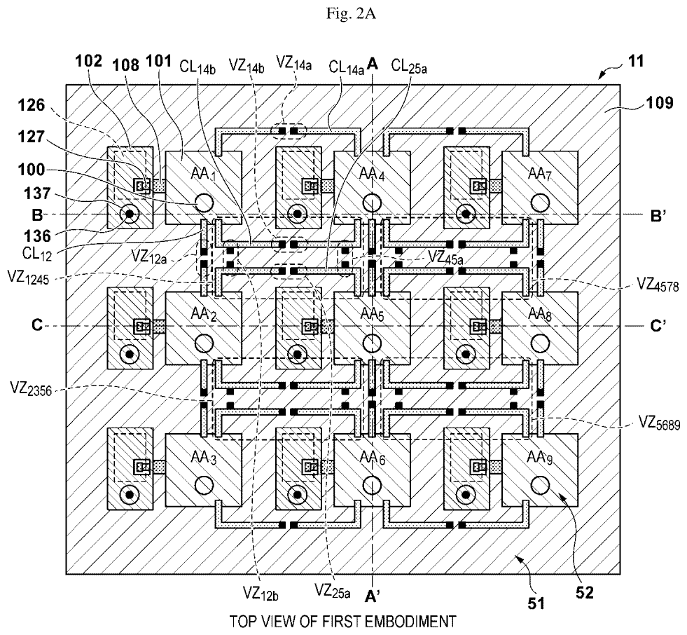

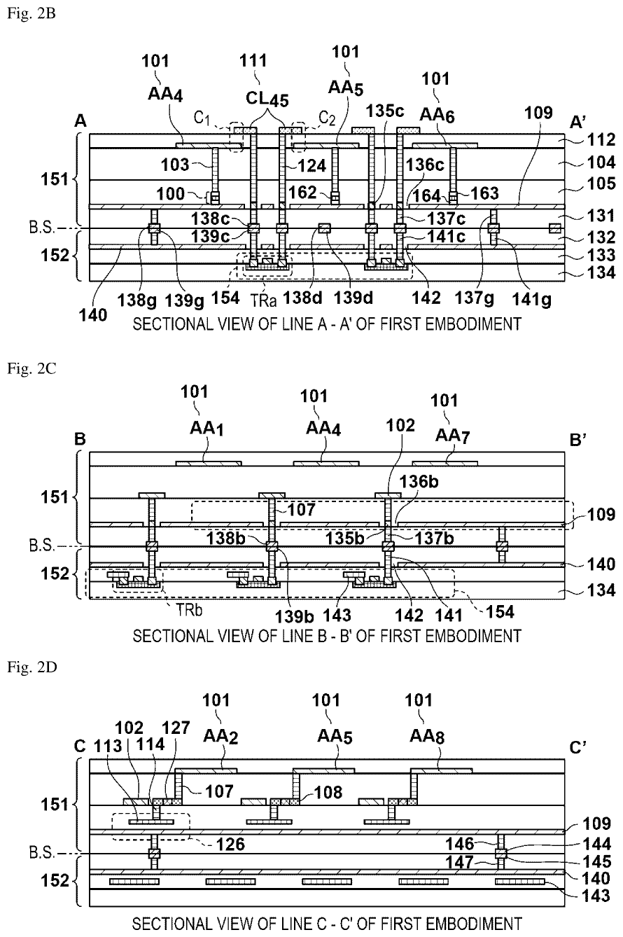

FIGS. 2A to 2D are views each showing a portion of the active antenna array 11 of the antenna apparatus 10. As shown in FIG. 2A, a square patch antenna is used as an antenna, and nine patch antennas are arranged in a 3×3 matrix. Each of the active antennas AA₁ to AA₉ is formed by integrating at least one antenna and the semiconductor layer 100 as an oscillation source, and emits a terahertz wave of an oscillation frequency f_{THz} in a direction perpendicular to the surface of the substrate. The semiconductor layer 100 of each active antenna includes a semiconductor structure for generating or detecting a terahertz wave, and this embodiment will describe an example of using a Resonant Tunneling Diode (RTD). Note that the semiconductor layer 100 is a semiconductor having nonlinearity of carriers (nonlinearity of a current along with a voltage change in the current-voltage characteristic) or an electromagnetic wave gain with respect to a terahertz wave, and is not limited to the RTD. Note that the bias control unit 12 shown in FIGS. 1A to 1D is a power supply for controlling a bias signal to be applied to the semiconductor layer 100, and is electrically connected to the semiconductor layer 100.

In the active antenna array 11 described in this embodiment, the active antennas are coupled by a coupling line CL as a transmission line, and are electrically connected. The coupling line CL as a transmission line can perform mutual injection locking between the antennas at the frequency f_{THz}. For example, the active antennas AA₁ and AA₂ are connected by a coupling line CL₁₂, and an impedance variable device VZ₁ for adjusting the impedance of the coupling line between the active antennas AA₁ and AA₂ is provided at the intermediate point of the coupling line CL₁₂. In the example of the 3×3 array shown in FIG. 2A, two coupling line CL₁₄ₐ and CL_{14b} as microstrip lines are connected to establish synchronization between active antennas AA₁ and AA₄ in the horizontal direction. The coupling line CL₁₄ₐ and CL_{14b} are connected to impedance variable device VZ₁₄ₐ and VZ_{14b}, respectively. Similarly, the coupling line CL₁₂ for establishing synchronization in the vertical direction and an impedance variable device VZ₁₂ₐ connected to the intermediate point of the coupling line CL₁₂ are arranged between the active antennas AA₁ and AA₂.

### (Arrangement of Active Antenna)

FIGS. 2B to 2D are sectional views of the active antenna array 11 taken along lines A-A′, B-B′, and C-C′, respectively. The active antenna AA serves as a resonator that causes a terahertz wave to resonate and a radiator that transmits or receives the terahertz wave. In the antenna array, the active antennas can be arranged at a pitch (interval) equal to or smaller than the wavelength of the detected or generated terahertz wave or a pitch (interval) of an integer multiple of the wavelength. The active antenna AA includes at least the conductor layer (antenna layer or upper conductor layer) 101 (AA₁) as the upper conductor of the patch antenna, a conductor layer 109 as a GND layer and a reflector layer, and the semiconductor layer 100 arranged between the conductor layers 101 and 109. The semiconductor layer 100 uses a Resonant Tunneling Diode (RTD) for a semiconductor structure 162. The RTD is a typical semiconductor structure having an electromagnetic wave gain in the frequency band of the terahertz wave, and is also called an active layer. The active antenna AA further includes a via 103 for connecting the conductor layer 101 and the semiconductor layer 100, and a conductor layer 111 as the upper conductor of the coupling line CL. A conductor layer 102 forming a bias wiring is arranged between the conductor layers 101 and 109, and is located at the intermediate point between dielectric layers 104 and 105. The bias wiring layer 102 is connected to the conductor layer 101 via a wiring 108 and a via 107. The conductor layer 109 as a GND layer is grounded.

As shown in FIG. 2B, in the semiconductor layer 100, a lower electrode layer 164, the semiconductor structure 162, and an upper electrode layer 163 are stacked in this order from the side of the conductor layer 109, and are electrically connected. The semiconductor structure 162 is a semiconductor structure having nonlinearity and an electromagnetic wave gain with respect to a terahertz wave, and an RTD is used in this embodiment. The upper electrode layer 163 and the lower electrode layer 164 have a structure serving as an electrode layer for connecting contact electrodes (ohmic and Schottky electrodes) above and below the semiconductor structure 162 and upper and lower wiring layers in order to apply a potential difference or a current to the semiconductor structure 162. The upper electrode layer 163 and the lower electrode layer 164 can be made of a metal material (Ti/Pd/Au/Cr/Pt/AuGe/Ni/TiW/Mo/ErAs or the like) known as an ohmic electrode or Schottky electrode, or a semiconductor doped with impurities.

The active antenna AA₁ includes the conductor layer 101, the semiconductor layer 100, the conductor layer 109 (reflector), the dielectric layers 104 and 105, and the via 103 that connects the conductor layer 101 and the semiconductor layer 100. To apply a control signal to the semiconductor layer 100, the conductor layer 102 forming the bias wiring, the via 107, a Metal Insulator Metal (MIM) capacitor 126, and a resistance layer 127, which are individually provided for each antenna, are connected to the active antenna AA₁. The MIM capacitor 126 is a capacitive element that sandwiches an insulator layer by a metal, and is arranged to suppress a low-frequency parasitic oscillation caused by a bias circuit. The MIM capacitor 126 of this embodiment uses a structure in which part of a dielectric layer 106 is sandwiched by a conductor layer 113 and the conductor layer 109 as GND.

### (Antenna Array)

To increase the gain of the active antenna array 11, it is considered that the plurality of active antennas AA₁ to AA₉ are arranged in an array. The semiconductor layer 100 including the RTD is arranged in each active antenna, as described above, and the gain of the active antenna is increased by performing mutual injection locking between the active antennas. To establish synchronization among the plurality of active antennas AA₁ to AA₉, the coupling lines CL each coupling adjacent antennas are necessary. Each active antenna and each coupling line are connected by capacitive coupling. The length of the coupling line CL is designed to satisfy a phase matching condition in one or both of the horizontal direction (magnetic field direction/H direction) and the vertical direction (electric field direction/E direction) if the adjacent antennas are connected by the coupling line. Note that the present invention is applicable not only to an antenna that emits a horizontally/vertically polarized wave but also to an antenna that emits a circularly polarized wave. For example, by setting the conductor layer 101 of the patch antenna to have a rectangular shape other than a square and forming a notch, it is possible to emit a circularly polarized wave. Alternatively, an antenna, different from a patch antenna, that emits a circularly polarized wave may be applied.

In an example, the coupling line is designed to have such length that the electrical length between the RTDs of the adjacent antennas is equal to an integer multiple of 2π. For example, the coupling line CL₁₄ extending in the horizontal direction has such length that the electrical length between the semiconductor layers 100 of the active antennas AA₁ and AA₄ is equal to 4π. Furthermore, the coupling line CL₁₂ extending in the vertical direction has such length that the electrical length between the semiconductor layers 100 of the active antennas AA₁ and AA₂ is equal to 2π. At this time, the electrical length indicates a wiring length considering the propagation speed of a high frequency wave that propagates in the coupling line. With this design, the semiconductor layers 100 of the active antennas AA₁ to AA₉ are mutual injection-locked in the positive phase. Note that the error range of the length is ±¼π.

The impedance variable device VZ₁₂ for adjusting the impedance of the coupling line CL₁ is provided at the intermediate point of the coupling line CL₁ that connects the adjacent active antennas AA₁ and AA₂. In this embodiment, as the impedance variable device VZ, a MOSFET advantageous in circuit integration and a reduction in cost is used. The first substrate 151 on which an antenna array for transmitting/receiving a terahertz wave and the semiconductor layer 100 formed from a compound semiconductor (semiconductor structure) are integrated and the second substrate 152 including a CMOS integrated circuit for antenna array control are bonded at a bonding surface B.S. This arrangement is implemented by stacking, by a semiconductor stacking technique, an antenna substrate of a compound semiconductor including an antenna array and an Si integrated circuit substrate.

### (Explanation of Stacked Structure)

As shown in FIG. 2B, in the semiconductor layer 100, the lower electrode layer 164, the semiconductor structure 162, and the upper electrode layer 163 are stacked in this order from the side of the conductor layer 109, and are electrically connected. The semiconductor structure 162 is a semiconductor structure having nonlinearity and an electromagnetic wave gain with respect to a terahertz wave, and an RTD is used in this embodiment. The upper electrode layer 163 and the lower electrode layer 164 have a structure serving as an electrode layer for connecting contact electrodes (ohmic and Schottky electrodes) above and below the semiconductor structure 162 and upper and lower wiring layers in order to apply a potential difference or a current to the semiconductor structure 162. The upper electrode layer 163 and the lower electrode layer 164 can be made of a metal material (Ti/Pd/Au/Cr/Pt/AuGe/Ni/TiW/Mo/ErAs or the like) known as an ohmic electrode or Schottky electrode, or a semiconductor doped with impurities.

One active antenna AA is formed from the conductor layer 101 of the antenna, the semiconductor layer 100, the conductor layer 109 (reflector), the dielectric layers 104 and 105, and the via 103 that connects the conductor layer 101 and the semiconductor layer 100. To apply a control signal to the semiconductor layer 100, the conductor layer 102 forming the bias wiring, the via 107, the MIM capacitor 126, and the resistance layer 127, which are individually provided for each antenna, are connected to the active antenna AA, as shown in FIGS. 2C and 2D. The MIM capacitor 126 is a capacitive element that is arranged to suppress a low-frequency parasitic oscillation caused by a bias circuit. The MIM capacitor 126 has conductive patterns and an insulator layer. The conductive patterns sandwich an insulator layer. The active antennas AA₁ to AA₉ are connected by the coupling lines CL for establishing synchronization between the antennas at a terahertz frequency.

The bonding surface B.S. is provided on the lower surface of the first substrate 151 on which the antenna array and the compound semiconductor are integrated, and the first substrate 151 is bonded, via the bonding surface B.S., to the second substrate 152 including the integrated circuit. At this time, “bonded” is defined as sharing the same bonding surface B.S. by the first substrate 151 and the second substrate 152. The bonding second substrate 152 is formed by including a semiconductor substrate as a base material and an integrated circuit region where a driving circuit is formed. The two different kinds of substrates 151 and 152 are bonded by metal bonding such as Cu—Cu bonding, insulator bonding such as SiOₓ—SiOₓ bonding, hybrid bonding as a combination of these, adhesive bonding using an adhesive such as BCB, or the like. As a bonding process, low-temperature bonding using plasma activation or conventional thermocompression bonding is used. A method of bonding semiconductor wafers of the same size, a method of bonding semiconductor wafers of different sizes, a method (tiling) of separately bonding a plurality of semiconductor chips to a wafer, or the like is used.

In the active antenna array 11, the mesa structure of the semiconductor layer 100 is embedded in the dielectric layer 105 to cover the periphery. The surface of the dielectric layer 105 on the side of the bonding surface B.S. is planarized, and the conductor layer 109 as a reflector is provided on the planarized surface. The dielectric layer 105 plays the role as a dielectric material forming the antenna and the role of a planarization film in a manufacturing process of transferring the mesa structure of the semiconductor layer 100 to the different type of substrate. As the dielectric layer 105, for example, an inorganic insulating material such as silicon oxide (SiOₓ), silicon nitride (SiNₓ), silicon oxynitride (SiON), carbon-containing silicon oxide (SiOC), or silicon carbide (SiC) is used. The active antenna array 11 is formed from an antenna region 52 (in the conductor layer 101 as the upper conductor of the patch antenna) where the antennas are provided, and a peripheral region 51, outside the antenna region, where the bias wiring and coupling lines CL are provided. The antenna region 52 indicates a region overlapping the conductor layer 101 as the upper conductor of each patch antenna in the stacking direction of the substrates, and the peripheral region 51 indicates a region not overlapping the conductor layer 101 as the upper conductor of each patch antenna. In an example, the peripheral region 51 is a region not overlapping the conductor layer 101 as the upper conductor of each patch antenna, and a region separated from the conductor layer 101 by 1/10 or more of the wavelength of the terahertz wave. That is, the antenna region 52 is a region including the near field of the terahertz wave, and the peripheral region 51 is a region not including the near field of the terahertz wave.

On the side of the first substrate 151 opposite to the second substrate 152, the conductor layer 109, the dielectric layer 105, the dielectric layer 104, and a dielectric layer 112 are stacked in this order. In the dielectric layers 105 and 104, the via 103, the via 107, and a via 124, and the conductor layer 101, the conductor layer 102, and the conductor layer 111 respectively connected to the vias are formed. The surface of the first substrate 151 on the side of the bonding surface B.S. to the second substrate 152 is arranged at a position facing the semiconductor layer 100 via the conductor layer 109 as the reflector. The conductor layer 102 as a wiring layer is provided at the intermediate point between the conductor layer 101 as an antenna layer and the conductor layer 109 as a reflector layer. On the planarized surface of the dielectric layer 105 of the first substrate 151 on the side of the second substrate 152, the conductor layer 109 and an insulator layer 131 are stacked in this order, and a through via 137 and a bonding electrode layer 138 are formed in the insulator layer 131. The insulator layer 131 and the electrode layer 138 are planarized at the bonding surface B.S., and undergoes a bonding process in a state in which the flat bonding surface B.S. is exposed. In the second substrate 152, a semiconductor substrate 134 as a base material, an insulator layer 133, a conductor layer 140, and an insulator layer 132 are stacked in this order, and a via 141 and a bonding electrode layer 139 are formed in the insulator layer 132. The insulator layer 132 and the electrode layer 139 are planarized at the bonding surface B.S., and undergoes a bonding process in a state in which the flat bonding surface B.S. is exposed. Therefore, the bonding surface B.S. is provided between the conductor layer 109 as a reflector and the second substrate 152 as a control circuit substrate. In this arrangement, since the antennas and the control circuit are separated, it is possible to reduce noise caused by radio frequency interference between the active antenna array operating at a terahertz frequency and the control circuit operating at an RF frequency. The insulator layers 131 to 133 can be formed using an inorganic insulating material such as silicon oxide (SiOₓ), silicon nitride (SiNₓ), silicon oxynitride (SiON), carbon-containing silicon oxide (SiOC), or silicon carbide (SiC). Furthermore, for the insulator layer 131, a compound semiconductor substrate may be used.

FIG. 2B is a sectional view of the antenna array 11 taken along the line A-A′. The coupling line CL of the first substrate 151 on which the compound semiconductor is integrated and the conductor layer 109 as a reflector are electrically connected to a transistor TRa (MOSFET) for phase control arranged in the integrated circuit region of the second substrate 152 and the conductor layer 140. The conductor layer 111 as the upper conductor of the coupling line CL of the first substrate 151 is connected to the via 124 formed in the dielectric layers 104 and 105, and a wiring layer 135c provided in an opening 136c of the dielectric layer 104. Furthermore, the wiring layer 135c is electrically connected to a through via 137c provided in the insulator layer 131, and a bonding electrode layer 138c, in this order. With this arrangement, the conductor layer 111 reaches the bonding surface B.S. In addition, the transistor TR formed in the integrated circuit region of the second substrate 152 is connected to a via 141c formed in the integrated circuit region, and a bonding electrode layer 139c in this order to reach the bonding surface B.S. The electrode layer 138c of the first substrate 151 and the electrode layer 139c of the second substrate 152 are electrically connected at the bonding surface B.S. to render the coupling line CL of the antenna array and the transistor TRa of an integrated circuit region 154 conductive, thereby making it possible to apply a control signal. Note that the transistor TRa and a transistor TRb are formed near the surface of the semiconductor substrate 134 as the base material of the second substrate 152.

FIG. 2B is a sectional view of the active antenna array 11 taken along the line A-A′. The coupling line CL of the first substrate 151 on which the compound semiconductor is integrated and the conductor layer 109 as a reflector are electrically connected to the transistor TRa (MOSFET) for phase control arranged in the integrated circuit region 154 of the second substrate 152 and the conductor layer 140 corresponding to second GND. The conductor layer 111 is the upper conductor of the coupling line CL of the first substrate 151. The conductor layer 111 is electrically connected to the via 124 formed in the dielectric layers 104 and 105, the wiring layer 135c provided in the opening 136c of the dielectric layer 104, the through via 137c provided in the insulator layer 131, and the bonding electrode layer 138c in this order to be electrically connected to the bonding surface B.S. Furthermore, the transistor TR formed in the integrated circuit region 154 of the second substrate 152 is connected to the via 141c formed in the integrated circuit region 154, and the bonding electrode layer 139c in this order to reach the bonding surface B.S. The electrode layer 138c of the first substrate 151 and the electrode layer 139c of the second substrate 152 are electrically connected at the bonding surface B.S. to render the coupling line CL of the antenna array and the transistor TRa of an integrated circuit region 154 conductive, thereby making it possible to apply a control signal. Note that the transistors TRa and TRb are formed near the surface of the semiconductor substrate 134 as the base material of the second substrate 152.

Similarly, the conductor layer 109 as a reflector in the antenna of the first substrate 151 is electrically connected to a through via 137g provided in the insulator layer 131, and a bonding electrode layer 138g in this order to reach the bonding surface B.S. The conductor layer 140 as GND of the second substrate 152 is connected to a via 141g formed in the insulator layer 132 and a bonding electrode layer 139g in this order to reach the bonding surface B.S. The electrode layer 138g of the first substrate 151 and the electrode layer 139g of the second substrate 152 are electrically connected at the bonding surface B.S., thereby sharing the GND potential of both the substrates. As an example of enhancing the bonding strength, dummy electrode layers 138d and 139d not connected to signal lines may be provided on the bonding surface B.S. By widely distributing the dummy electrode layers 138d and 139d in a region where no wiring electrode is necessary, the bonding strength can be enhanced, thereby improving the yield and reliability. Furthermore, by widely distributing and arranging the GND electrode layers 138g and 139g and the dummy electrode layers 138d and 139d over the entire bonding surface B.S., it is possible to reduce the influence of electromagnetic wave noise on the terahertz antennas of the first substrate 151, which is caused by the integrated circuit of the second substrate 152.

Similarly, the conductor layer 109 as a reflector in the antenna of the first substrate 151 is electrically connected to the through via 137g provided in the insulator layer 131, and the bonding electrode layer 138g in this order to reach the bonding surface B.S. The conductor layer 101 as the upper conductor and the conductor layer 109 having an area larger than that of the upper conductor formed in the conductor layer 101 and operating as GND function as a patch antenna that resonates with the terahertz wave. The conductor layer 140 as GND of the second substrate 152 is connected to the via 141g formed in the integrated circuit region 154 and the bonding electrode layer 139g in this order to reach the bonding surface B.S. The electrode layer 138g of the first substrate 151 and the electrode layer 139g of the second substrate 152 are electrically connected at the bonding surface B.S., thereby sharing the GND potential of both the substrates. By arranging the conductor layer 140 as second GND separately from the conductor layer 109 as a reflector and first GND, it is possible to reduce noise caused by radio frequency interference between the active antenna operating at a terahertz frequency and the control circuit operating at an RF frequency. To increase the effect of noise reduction, the conductor layers 109 and 140 each serving as GND are preferably formed in a solid pattern. As an example of enhancing the bonding strength, dummy electrode layers 138b and 139b not connected to signal lines may be provided on the bonding surface B.S. By widely distributing the dummy electrode layers 138b and 139b in a region where no wiring electrode is necessary, the bonding strength can be enhanced, thereby contributing to improvement of the yield and reliability. Furthermore, by widely distributing and arranging the GND electrode layers 138g and 139g and the dummy electrode layers 138b and 139b on the bonding surface B.S., it is possible to reduce the influence of electromagnetic wave noise on the antennas of the first substrate 151, which is caused by the integrated circuit of the second substrate.

FIG. 2C is a sectional view of the active antenna array 11 taken along the line B-B′. The conductor layer 102 forming the bias wiring connected to the compound semiconductor layer of the first substrate 151 is electrically connected to the transistor TRb (MOSFET) as the bias control circuit provided in the integrated circuit region of the second substrate 152. The conductor layer 102 is electrically connected to the via 107 formed in the dielectric layer 105, a wiring layer 135b provided in an opening 136b of the conductor layer 109 as a reflector, a through via 137b provided in the insulator layer 131, and the bonding electrode layer 138b in this order. Thus, the wiring layer 102 reaches the bonding surface B.S. Similarly, the transistor TRb formed in the integrated circuit region of the second substrate 152 is connected to a via 141b formed in the integrated circuit region, and the bonding electrode layer 139b in this order to reach the bonding surface B.S. The electrode layer 138b of the first substrate 151 and the electrode layer 139b of the second substrate 152 are electrically connected at the bonding surface B.S. Therefore, the bias wiring layer 102 of the antenna array and the transistor TRa of the integrated circuit region are rendered conductive, thereby making it possible to individually apply a control signal to each antenna.

FIG. 2C is a sectional view of the active antenna array 11 taken along the line B-B′. The bias wiring layer 102 connected to the compound semiconductor layer of the first substrate 151 is electrically connected to the transistor TRb (MOSFET) as the bias control circuit provided in the integrated circuit region 154 of the second substrate 152. The bias wiring layer 102 of the first substrate 151 is electrically connected to the via 117, the wiring layer 135b provided in the opening 136b of the conductor layer 109 as a reflector, the through via 137b provided in the insulator layer 131, and the bonding electrode layer 138b in this order to be electrically connected to the bonding surface B.S. At this time, the opening 136 and the respective electrodes (the wiring layer 135, the through via 137, and the electrode layer 138) that electrically connect the first substrate 151 and the second substrate 152 are provided in the peripheral region 51. By arranging the opening 136 of the reflector and the bonding member at positions not overlapping the antenna region, the radiation efficiency and the effect of measures against noise are expected. However, it is not always necessary to arrange them in the peripheral region 51. For example, if they are sufficiently small (typically, 1/10 or less of an electrical length λ), as compared with the electrical length of an electromagnetic wave expected to propagate to the opening 136, the wiring layer 135, and the through via 137, the influence on the antenna is negligible. In this case, the opening 136, the wiring layer 135, and the through via 137 may be arranged in the antenna region.

Similarly, the transistor TRb formed in the integrated circuit region 154 of the second substrate 152 is electrically connected to the via 141b formed in the integrated circuit region 154 and the bonding electrode layer 139b in this order to be electrically connected to the bonding surface B.S. When the electrode layer 138b of the first substrate 151 and the electrode layer 139b of the second substrate 152 are electrically connected at the bonding surface B.S., the bias wiring layer 102 of the antenna array and the transistor TRa of the integrated circuit region 154 are rendered conductive. This can make it possible to individually apply a control signal to each antenna.

The transistor TRa as a phase control circuit adjusts the impedance of the coupling line CL by a variable resistance or a switch operation by connecting the source-drain path of the MOSFET to the intermediate point of the coupling line CL. The transistor TRa for phase control can be used as a variable capacitor by connecting the gate-source path. The MOSFET of the transistor TRa as a bias control circuit also serves as a bias control unit, and operates as a switching regulator to supply a bias signal to the semiconductor layer 100. As another arrangement, an arrangement in which a voltage is supplied from the outside of the second substrate 152 by additionally providing a terminal for applying a bias signal on the second substrate 152 and causing the transistor TRa to operate as an analog switch may be adopted.

### (Device Operation)

The active antenna array 11 shown in FIGS. 2A to 2D uses a hybrid coupler as an impedance variable device. The active antenna array 11 includes four hybrid couplers VZ₁₂₄₅, VZ₂₃₅₆, VZ₄₅₇₈, and VZ₅₆₈₉, each of which connect the adjacent active antennas of a 2×2 array. For example, the active antennas AA₁, AA₂, AA₄, and AA₅ are connected to the hybrid coupler VZ₁₂₄₅ arranged at the intermediate point between two coupling lines CL_{14b} and CL₂₅ₐ. The hybrid coupler VZ₁₂₄₅ is formed from four impedance variable devices VZ_{12b}, VZ₄₅ₐ, VZ_{14b}, and VZ₂₅ₐ. Among them, the impedance variable devices VZ_{12b} and VZ₄₅ₐ are connected to couple the two coupling lines CL_{14b} and CL₂₅ₐ in the vertical direction, and switch the coupling between the coupling lines CL_{14b} and CL₂₅ₐ by ON/OFF switches. Furthermore, the impedance variable device VZ_{14b} is arranged at the intermediate point of the coupling line CL_{14b}, and the impedance variable device VZ₂₅ₐ is arranged at the intermediate point of the coupling line CL₂₅ₐ, thereby serving as switches for switching the coupling between the adjacent antennas. It is possible to generate a phase difference between ports by controlling multiplexing in the hybrid coupler VZ₁₂₄₅. In addition, it is possible to change the electrical length of the coupling line CL by simply changing the impedance of the impedance variable device VZ from capacitive to inductive. In this case, it is possible to adjust the phase difference between the adjacent active antennas to a given value, thereby adjusting the phases of the coupling lines CL among the active antennas AA₁ to AA₉. This generates arbitrary phase differences among the active antennas AA₁ to AA₉, thereby making it possible to perform beamforming.

In the active antenna array of the terahertz wave, to individually control each antenna, a plurality of wirings such as a bias line for supplying power to the compound semiconductor, a synchronization line for controlling synchronization between the antennas, and a control line for injecting a baseband signal into the antenna are necessary. On the other hand, to improve the gain of the antenna, it is necessary to increase the number of antennas but wiring inductance caused by the layout increases along with an increase in number of antennas, thereby interfering with implementation of a high frequency. To the contrary, in this embodiment, the antenna substrate (first substrate 151) of the compound semiconductor including the antenna array and the Si integrated circuit substrate (second substrate 152) are stacked by a semiconductor bonding technique. This eliminates the need to take an implementation form of integrating or externally connecting a peripheral circuit necessary to control the active antenna array onto the compound semiconductor substrate. This can suppress an increase in inductance caused by wiring routing, and typically suppress inductance to 1 nH or less, thereby suppressing a signal loss or signal delay of the baseband signal subjected to modulation control at a high frequency of 1 GHz or more.

Since, in the periphery of the antenna, there is no circuit that is not related to transmission/reception of the terahertz wave or the number of such circuits can be made sufficiently small, noise by unnecessary reflection is reduced, thereby making it possible to exhibit the characteristic of the antenna at the maximum. If the bias signal of the compound semiconductor and the like are controlled for each antenna, each bias wiring needs to be individually arranged. To the contrary, in this embodiment, the first substrate 151 including the antenna array can directly be connected to the integrated circuit of the second substrate 152 via the through vias 137b, 137c, 137d, and 137g. If the active antenna array is used, a wiring can be arranged on the rear side (that is, the rear side of the conductor layer 109 as a reflector) of the antenna substrate (first substrate 151) of the compound semiconductor including the antenna array. Therefore, it is possible to increase the number of active antennas included in the antenna array without receiving the influence of the layout. Furthermore, the second substrate 152 including the integrated circuit can form a complex circuit such as a detection circuit or a signal processing circuit using the conventional CMOS integrated circuit technique. Therefore, by using the arrangement described in this embodiment, it is possible to sophisticate the antenna apparatus and reduce the cost, and thus readily use an electromagnetic wave in the terahertz band.

### Second Embodiment

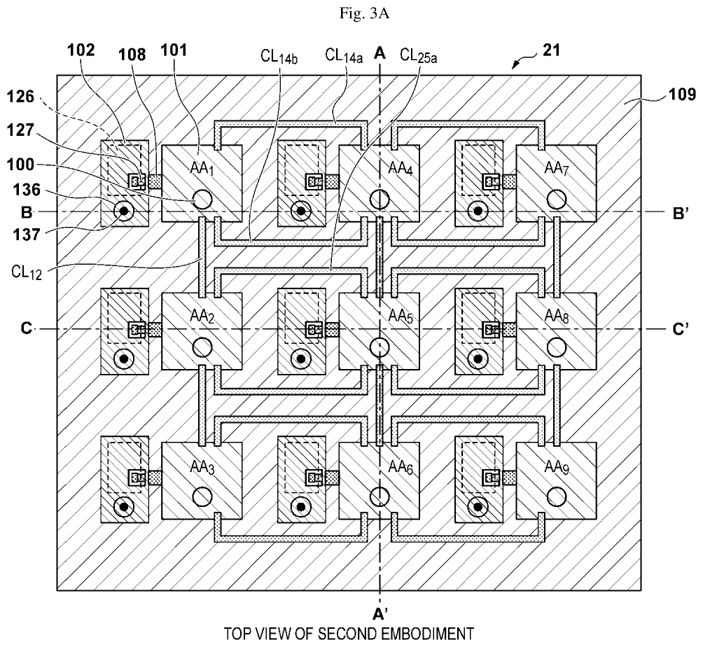

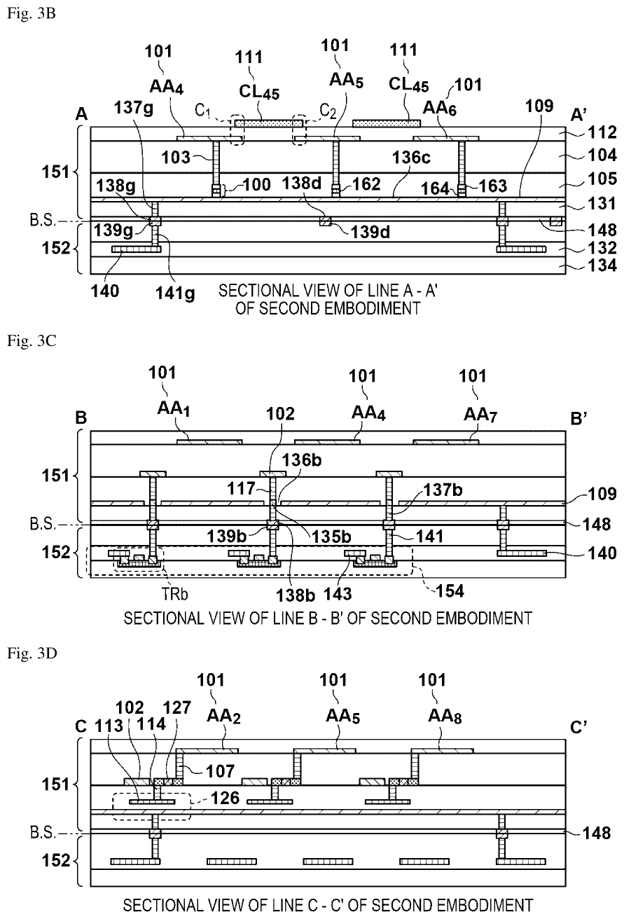

FIG. 3A is a top view of an antenna array 21 according to the second embodiment. FIGS. 3B, 3C, and 3D are sectional views of the antenna array 21 taken along lines A-A′, B-B′, and C-C′, respectively. In the antenna array 21, as an insulator layer 131 of a first substrate 151 on which a compound semiconductor is integrated, a semi-insulating InP substrate (4 inches) as a compound semiconductor substrate on which a compound semiconductor is crystal-grown is used. In this embodiment, assume that the insulator layer 131 is a semiconductor layer. From the viewpoint of reduction of wiring inductance, the thickness of the semiconductor substrate is preferably 100 μm or less, and more preferably 10 μm or less. The board thickness is designed within a range of 1/10 or less of the wavelength of the terahertz wave to be operated. In an example, the board thickness is 1/20 or less of the wavelength of the terahertz wave to be operated.

A bonding surface B.S. is provided on the lower surface of the semiconductor substrate 131 as a base material of the first substrate 151, and a second substrate 152 including an integrated circuit is bonded. In this embodiment, hybrid bonding of Cu—Cu bonding and SiOₓ—SiOₓ bonding is used to perform tiling of bonding the cut first substrate 151 to the 12-inch Si integrated circuit substrate.

In the first substrate 151, an insulator layer 148, the semiconductor substrate 131, a conductor layer 109, and dielectric layers 105, 104, and 112 are stacked in this order from the side of the bonding surface B.S. to the second substrate 152. In the dielectric layers 105 and 104, vias 103, 107, and 117 and conductor layers 101, 102, and 111 are formed. The surface of the first substrate 151 on the side of the bonding surface B.S. to the second substrate 152 is arranged at a position facing the semiconductor layer 100 via the conductor layer 109 as the reflector. A through via 137 formed to extend through the insulator layer 131 is formed in the semiconductor substrate 131. As the material of the through via 137, copper (Cu) or gold (Au) is preferably used. The insulator layer 148 and an electrode layer 138 for bonding are planarized at the bonding surface B.S., and undergoes a bonding process in a state in which the flat bonding surface B.S. is exposed. In the second substrate 152, a semiconductor substrate 134 as a base material and an insulator layer 132 are stacked in this order, and a conductor layer 140 forming a multilayer wiring, a via 141, and a bonding electrode layer 139 are formed in the insulator layer 132. An insulator layer 132 and the electrode layer 139 are planarized at the bonding surface B.S., and undergoes a bonding process in a state in which the flat bonding surface B.S. is exposed. For the insulator layers 132 and 148, an inorganic insulating material such as silicon oxide (SiOₓ), silicon nitride (SiNₓ), silicon oxynitride (SiON), carbon-containing silicon oxide (SiOC), or silicon carbide (SiC) is used. As described above, the board thickness is designed within a range of 1/10 or less of the wavelength of the terahertz wave to be operated. Therefore, the distance between the conductor layer 111 and the semiconductor substrate 134 can be made 1/10 or less of the wavelength of the terahertz wave, and it is possible to reduce the impedance of the through via 137, the bonding electrode layers 138 and 139, and the via 141.

FIG. 3B is a sectional view of the antenna array 21 taken along the line A-A′. The conductor layer 109 playing the role of a reflector in active antennas AA₁ to AAₙ of the first substrate 151 is electrically connected to a through via 137g provided in the insulator layer 131 and a bonding electrode layer 138g formed in the insulator layer 148 in this order to be electrically connected to the bonding surface B.S. The conductor layer 140 as GND of the second substrate 152 is connected to a via 141g formed in an integrated circuit region 154 and a bonding electrode layer 139g in this order to reach the bonding surface B.S. The electrode layer 138g of the first substrate 151 and the electrode layer 139g of the second substrate 152 are electrically connected at the bonding surface B.S., thereby sharing the GND potential of both the substrates.

FIG. 3C is a sectional view of the active antenna array 21 taken along the line B-B′. A bias wiring layer 102 connected to a semiconductor layer 100 of the first substrate 151 is electrically connected to a transistor TRb (MOSFET) for bias control provided in the integrated circuit region 154 of the second substrate 152. The bias wiring layer 102 is connected to a via 117 formed in the dielectric layer 105, a wiring layer 135b provided in an opening 136b, a through via 137b provided in the semiconductor substrate 131, and an electrode layer 138b provided in the insulator layer 148 in this order to be electrically connected to the bonding surface B.S. Similarly, a transistor TRb formed in the integrated circuit region 154 of the second substrate 152 is connected to a via 141b formed in the integrated circuit region 154 and a bonding electrode layer 139b in this order to reach the bonding surface B.S.

At the bonding surface B.S. between the electrode layer 138b of the first substrate 151 and the electrode layer 139b of the second substrate 152, each antenna is individually, electrically connected. This renders the bias wiring layer 102 of the antenna array and the transistor TRa of the integrated circuit region 154 conductive, thereby making it possible to individually apply a control signal to each antenna. When the MOSFET of the transistor TRb also serves as a bias control unit, and operates as a switching regulator, the bias control wiring layer 102 individually controls a bias signal to the semiconductor layer 100. An arrangement in which a voltage is supplied from the outside of the second substrate 152 by additionally providing a terminal for applying a bias signal on the second substrate 152 and causing the transistor TRa to operate as an analog switch for individually turning on/off the antenna may be adopted. With this arrangement, a phase difference is given between adjacent antennas by individually changing the bias of each active antenna, thereby making it possible to implement beamforming.

### Third Embodiment

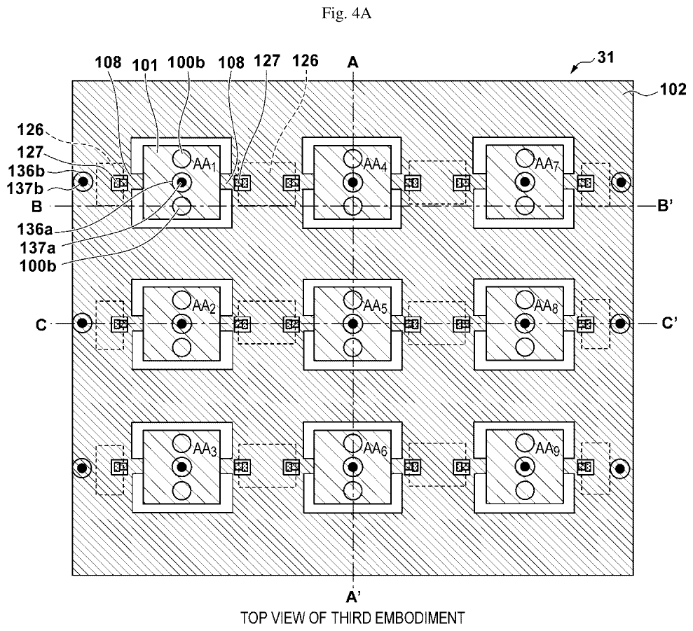

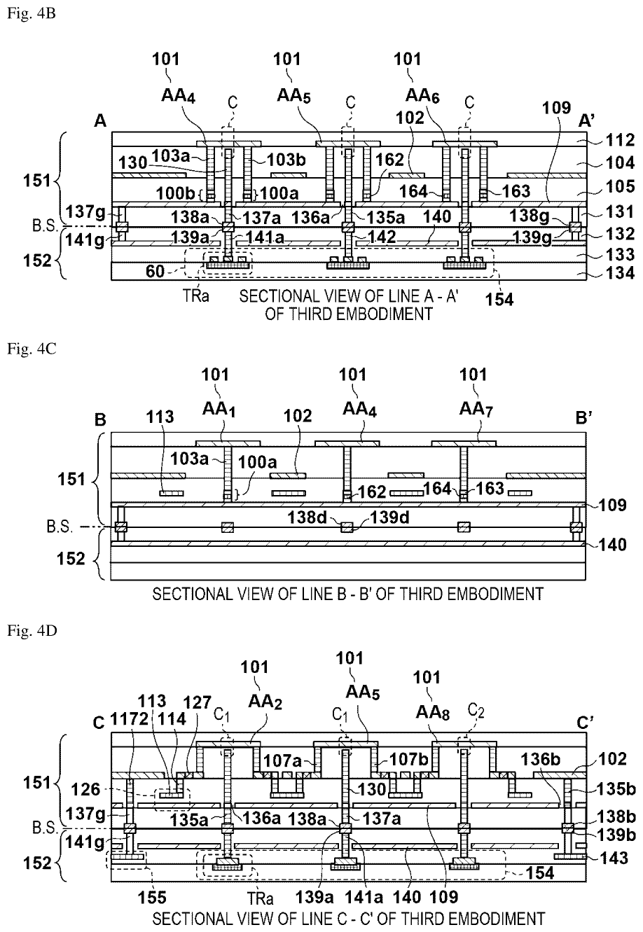

FIG. 4A is a top view of an antenna array 31 according to the third embodiment. FIGS. 4B to 4D are sectional views of the antenna array 31 taken along lines A-A′, B-B′, and C-C′, respectively. The antenna array 31 is an example in which wirings from a second substrate 152 including an integrated circuit are electrically connected to the respective active antennas AA₁ to AA₉. The active antenna AA₁ is formed from an conductor layer 101 of the antenna, two semiconductor layers 100a and 100b, a conductor layer 109 (reflector), dielectric layers 104 and 105, and vias 103a and 103b that connect the conductor layer 101 and the semiconductor layer 100. RTDs are used for the semiconductor layers 100a and 100b, and the two RTDs are arranged at positions facing each other with the center of the node (that is, a position at which the electric field of the standing wave of a terahertz wave becomes zero) of a resonance electric field in the antenna AA. In this arrangement, the two RTDs oscillate in a push-pull mode in which mutual injection locking occurs in a state (in opposite phases) in which the phases are reversed. As shown in FIG. 4A, the arrangement in which the RTDs are vertically and horizontally, symmetrically arranged in the antenna is an arrangement that can more easily obtain the effect of improvement of directivity along with an increase in number of arrays.

To generate a terahertz wave, in the semiconductor layer 100, an upper electrode layer 163, a semiconductor structure 162, and a lower electrode layer 164 are stacked in this order. The semiconductor structure 162 is the RTD formed in the semiconductor layer having nonlinearity or an electromagnetic wave gain with respect to a terahertz wave. The upper electrode layer 163 and the lower electrode layer 164 have a structure including an electrode layer for connecting contact electrodes above and below the semiconductor structure 162 and upper and lower wiring layers in order to apply a potential difference or a current to the RTD as the semiconductor structure 162. In this structure, the upper electrode layer 163 is connected to the via 103 and the lower electrode layer 164 is connected to the conductor layer 109, thereby giving a potential difference or a current to the semiconductor structure 162. Therefore, it can be said that the upper electrode layer 163 and the via 103, and the lower electrode layer 164 and the conductor layer 109 are connected to two power lines, respectively.

To apply a bias control signal to the semiconductor layer 100, a common bias wiring layer 102 is provided for all the active antennas AA₁ to AA₉. The position of the wiring layer 102 is set to be connected, at the position of the node of a resonance electric field formed on the active antennas AA₁ to AA₉ at a frequency f_{THz}, to the active antennas AA₁ to AA₉ by vias 107a and 107b arranged for the respective antennas. The wiring layer 102 is connected to a MIM capacitor 126 and a resistance layer 127 arranged for each antenna, and AC short-circuits a high frequency other than the frequency f_{THz}, thereby reducing an impedance at the high frequency. This suppresses multi-mode oscillation in the array antenna.

FIG. 3D is a sectional view of the antenna array 31 taken along the line C-C′. The bias wiring layer 102 connected to the semiconductor layer 100 of a first substrate 151 is electrically connected to a bias control wiring layer 143 provided in an integrated circuit region 154 of a second substrate 152. The wiring layer 102 is electrically connected to the via 117 formed in the dielectric layer 105, a wiring layer 135b provided in an opening 136b of the conductor layer 109, a through via 137b provided in a semiconductor substrate 131, and a bonding electrode layer 138b provided in an insulator layer 148 in this order to be electrically connected to the bonding surface B.S. Similarly, a transistor TRb formed in the integrated circuit region 154 of the second substrate 152 is connected to a via 141b formed in the integrated circuit region 154 and a bonding electrode layer 139b in this order to reach the bonding surface B.S. At the bonding surface B.S. between the electrode layer 138b of the first substrate 151 and the electrode layer 139b of the second substrate 152, the bias wiring layer 102 of the antenna array and the wiring layer 143 of the integrated circuit region 154 are rendered conductive, thereby making it possible to apply a bias control signal to all the antennas. The bias control wiring layer 143 is externally supplied with a voltage via an application terminal additionally provided on the second substrate 152.

Each of the active antennas AA₁ to AA₉ has a via 130 for coupling an injection locking signal from a master oscillator 60. The via 130 is capacitively coupled to the conductor layer 101 of the active antenna via a capacitor C, and the master oscillator 60 and the active antenna AA are electrically connected to be short-circuited with respect to a terahertz band and to be open with respect to an RF band. Furthermore, the connection position of the via 130 is set to be connected at the position of the node of the resonance electric field of the frequency f_{THz} in each of the active antennas AA₁ to AA₉. Thus, the via 130 has a high impedance at the frequency f_{THz} and a low impedance at a subharmonic frequency in the antenna, thereby implementing the terahertz radiation efficiency and the injection efficiency of a master signal.

The master oscillator 60 is an oscillation source that oscillates at the subharmonic frequency (for example, f_{THz}/2) of the terahertz wave, and controls the phase of each active antenna. The master oscillator 60 outputs a signal of an output larger than the output of a single active antenna serving as a slave. The active antenna AA is electrically connected, via the via 130 for master oscillation, to the gate of a transistor TRa (MOSFET) of the master oscillator 60 provided in the integrated circuit region 154 of the second substrate 152. The via 130 for master synchronization formed in the dielectric layers 104 and 105 of the first substrate 151 is electrically connected to a wiring layer 135a provided in an opening 136a of the conductor layer 109, a through via 137a provided in the insulator layer 131, and a bonding electrode layer 138a in this order to be electrically connected to the bonding surface B.S. Similarly, the transistor TRa formed in the integrated circuit region 154 of the second substrate 152 is electrically connected to a via 141a formed in the integrated circuit region 154 and a bonding electrode layer 139a in this order to be electrically connected to the bonding surface B.S.

The electrode layer 138a of the first substrate 151 and the electrode layer 139a of the second substrate 152 are electrically bonded at the bonding surface B.S. Therefore, the active antennas AA₁ to AA₉ and the transistor TRa for individually controlling each antenna arranged in the integrated circuit region 154 are rendered conductive in the terahertz band, thereby making it possible to apply a control signal. Each active antenna forms, with the upper electrode layer 163, the via 103, the lower electrode layer 164, and the conductor layer 109, a bias structure that gives a potential difference from above and below the semiconductor structure 162. A subharmonic signal from the master oscillator 60 is injected into the semiconductor layers 100a and 100b via the bias structure. Therefore, a power signal of the subharmonic frequency (for example, f_{THz}/2) from the master oscillator 60 is injected into the semiconductor layers 100a and 100b each formed from the RTD having the role of the oscillation source in the antenna, thereby making it possible to control the phase of each active antenna. The device having such arrangement serves as a master oscillator that is a low frequency oscillation circuit for outputting a low frequency (f_{THz}/n, n is a natural number) of 1/integer of the terahertz band, thereby performing mutual injection locking for the active antenna operating at the frequency f_{THz}. This can execute timing control of the active antenna array at the frequency f_{THz}, thereby reducing phase noise.

### Fourth Embodiment

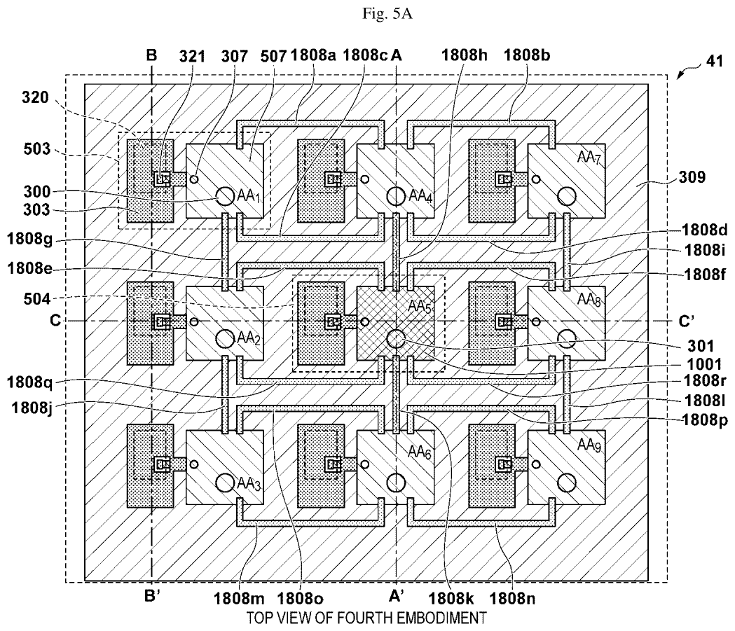

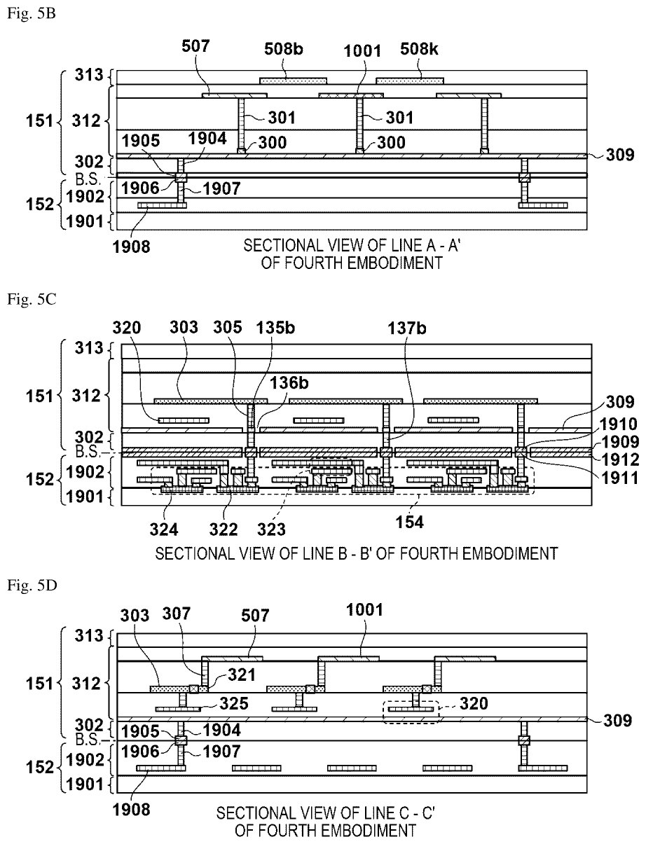

As the fourth embodiment, an example of using the present invention for a reception apparatus will be described. FIG. 5A is a schematic top view of an antenna array 41 according to this embodiment. FIGS. 5B to 5D are sectional views of the antenna array 41 taken along lines A-A′, B-B′, and C-C′, respectively. In the antenna array 41, one element at the center serves as a transmission antenna 504 for transmission and eight elements on the periphery of the transmission antenna 504 serve as reception antennas 503 for reception.

Each reception antenna 503 is a patch antenna having a structure in which a negative resistance element 300 and a dielectric 312 are sandwiched by a conductor layer 507 as an upper conductor for the reception antenna and a conductor layer 309 as a reflector. The upper terminal of the negative resistance element 300 is electrically connected to a via 301, and the via 301 is electrically connected to the conductor layer 507. Furthermore, the lower terminal of the negative resistance element 300 is electrically connected to the conductor layer 309 also serving as GND. The conductor layer 507 is set to be connected to a conductor layer 303 for an individual bias via a feeding via 307 for supplying power for a bias at the position of the node of a resonance electric field at a frequency f_{THz}. This structure can apply a bias above and below the negative resistance element 300. The conductor layer 303 is connected to a MIM capacitor 320 via a MIM capacitor connection portion 321. The MIM capacitor connection portion 321 includes a resistance layer using TiW, and plays the role of an AC short circuit series-connected to the MIM capacitor structure. If a signal of a predetermined bias voltage for generating a negative resistance is applied to the negative resistance element, self-oscillation is performed. At this time, destabilization of oscillation and a decrease in output caused by a parasitic oscillation are prevented. The transmission antenna 504 has substantially the same arrangement as that of the reception antenna except that a conductor layer 1001 as an upper conductor for the transmission antenna is provided. These antennas are connected by a plurality of transmission lines 1808a to 1808r and synchronized.

FIG. 5A shows the sectional structure of each reception antenna 503 or 504. A bonding surface B.S. exists on the rear surface of a first substrate 151, and bonds the outermost surface, on the side of the bonding surface B.C., of a semiconductor substrate 302 as the base material of the first substrate 151 to the outermost surface, on the side of the bonding surface B.C., of a second substrate 152 on which an integrated circuit is formed. In the second substrate 152, an integrated circuit region 154 is formed, and includes a control circuit 165 formed in a semiconductor substrate 1901 as a base material and an insulator layer 1902 of the integrated circuit. The bonding surface B.S. is a bonding interface at which a conductor layer 1910 formed on the rear surface of the semiconductor substrate 302 as the first substrate is directly bonded to the metal of a conductor layer 1911 exposed to the outermost layer of the second substrate 152. In this case, as a bonding form, metal bonding such as Cu—Cu bonding, insulator bonding such as SiOₓ—SiOₓ bonding, adhesive bonding using an adhesive such as BCB, or hybrid bonding as a combination of these can be used. As a bonding process, low-temperature bonding using plasma activation or conventional thermocompression bonding is used. A method of bonding semiconductor wafers of the same size, a method of bonding semiconductor wafers of different sizes, a method (tiling) of separately bonding a plurality of semiconductor chips to a wafer, or the like is used. In a driving circuit integrated on the second substrate 152 as well, the connections and structures have been described as examples of this embodiment but connections and structures are not limited to them.

Referring to FIG. 5B, the conductor layer 309 functioning as the reflector and GND of the first substrate 151 is electrically connected to a conductor layer 1908 as GND of the second substrate 152. The first substrate 151 includes a through via 1904 of GND extending from the conductor layer 309 in the direction of the bonding surface B.S., and an electrode layer 1905 as an GND terminal formed on the bonding surface. To the contrary, the conductor layer 1908 as GND of the second substrate 152 includes a wiring via 1907 of GND extending to the bonding surface B.S., and an electrode layer 1906 as a GND terminal formed on the bonding surface. Both the electrode layers 1905 and 1906 as the GND terminals are electrically coupled at the bonding portion, and share a GND potential.

Referring to FIG. 5C, the MIM capacitor 320 is provided in the bias path of the first substrate 151. The MIM capacitor 320 is a capacitor structure formed by the conductor layer 309 as GND and a conductor layer 325 connected to the end of the MIM capacitor connection portion 321 extending from the conductor layer 303 and connected to the conductor layer 507 of the reception antenna and the conductor layer 1001 of the transmission antenna via the feeding via 307. As long as a capacitance is formed, a Metal-Insulator-Semiconductor (MIS) structure may be adopted, and the present invention is not limited to this. Furthermore, the conductor layer 1908 as GND of the second substrate 152 may be shared with the GND potential and the GND layer of the integrated circuit region 154 of the second substrate 152 or a plurality of conductor layers 1908 may be provided. The conductor layers 309 and 140 each serving as GND may be formed in a solid pattern. As an example of enhancing the bonding strength, dummy electrode layers 1909 and 1912 not connected to signal lines may be provided on the bonding surface B.S. By widely distributing, in a solid pattern, the dummy electrode layers 1909 and 1912 in a region where no wiring electrode is necessary, the bonding strength can be enhanced, thereby contributing to improvement of the yield and reliability. Furthermore, this arrangement of solid GND can reduce the influence of electromagnetic wave noise on the terahertz antennas of the first substrate 151, which is caused by the integrated circuit of the second substrate.

Bias control will be described. A through via 305 connected to the conductor layer 303, a wiring layer 135b provided in an opening 136b of the conductor layer 309 as a reflector, and a through via 137b formed in the semiconductor substrate 302 are electrically connected, in this order, to the conductor layer (electrode layer) 1910 that forms an electrode as a bias terminal formed on the bonding surface B.S. Similarly, in the second substrate 152, the conductor layer 1911 as a bias terminal formed on the bonding surface B.S. is electrically connected to a MOSFET 322 as a transistor formed in the integrated circuit region 154. The MOSFET 322 forms a gate-grounded amplification circuit as an amplifier of the first stage. An amplified signal is further amplified by a source-grounded amplification circuit including a MOSFET 324. The gate-grounded amplification circuit and the source-grounded amplification circuit are coupled by a MIM capacitor 323 for AC coupling. The MIM capacitor 323 is merely an example, and may have an arrangement using the gate insulating film capacity of an FET. The MOSFET 322 also serves as a bias control unit, and the semiconductor substrate is connected via the MOSFET 322 to apply a bias voltage to the negative resistance element 300. Alternatively, an arrangement in which a terminal for applying a bias voltage may be provided on the second substrate 152 and a voltage is externally supplied may be adopted.

As in this embodiment, the first substrate 151 including the transmission/reception active antennas and the second substrate 152 including the electronic integrated circuit are bonded by a semiconductor bonding technique, thereby eliminating the need to integrate or implement the control circuit of the active antennas on the same plane. This reduces the space in the antenna, where the control circuit is arranged on the same plane, and it is possible to prevent the characteristic of the antenna from degrading due to coupling between the control circuit and the antennas. If bias control and the like are individually executed for each antenna, it is necessary to prepare a bias terminal for each antenna. However, in this embodiment, it is possible to readily perform connection to the integrated circuit region 154 by the through via 305. In this way, if the control circuit can be wired on the rear side of the first substrate 151, even if the active antenna array is used as in the above-described embodiment, it is possible to increase the number of antenna arrays without receiving the influence of an arrangement restriction and the like. Since the electronic integrated circuit of the second substrate 152 as the control circuit is made by the conventional CMOS technique, a complex circuit can be formed as a detection circuit or a signal processing circuit. This can broaden the utility of the terahertz wave reception apparatus using the active antennas according to this embodiment.

### Fifth Embodiment

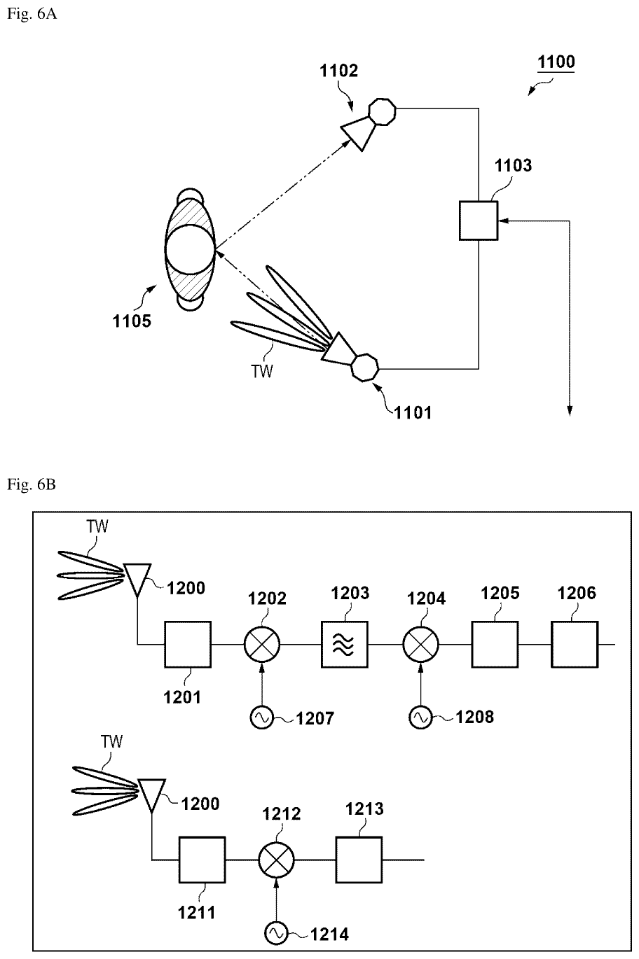

This embodiment will describe a case in which the antenna apparatus of one of the above-described embodiments is applied to a terahertz camera system (image capturing system). The following description will be provided with reference to FIG. 6A. A terahertz camera system 1100 includes a transmission unit 1101 that emits a terahertz wave, and a reception unit (detection unit) 1102 that detects the terahertz wave. Furthermore, the terahertz camera system 1100 includes a control unit 1103 that controls the operations of the transmission unit 1101 and the reception unit 1102 based on an external signal, processes an image based on the detected terahertz wave, or outputs an image to the outside. The antenna apparatus of each embodiment may serve as the transmission unit 1101 or the reception unit 1102.

The terahertz wave emitted from the transmission unit 1101 is reflected by an object 1105, and detected by the reception unit 1102. The camera system including the transmission unit 1101 and the reception unit 1102 can also be called an active camera system. Note that in a passive camera system without including the transmission unit 1101, the antenna apparatus of each of the above-described embodiments can be used as the reception unit 1102.

By using the antenna apparatus of each of the above-described embodiments that can perform beamforming, it is possible to improve the detection sensitivity of the camera system, thereby obtaining a high quality image.

### Sixth Embodiment

This embodiment will describe a case in which the antenna apparatus of one of the above-described embodiments is applied to a terahertz communication system (communication apparatus). The following description will be provided with reference to FIG. 6B. The antenna apparatus can be used as an antenna 1200 of the communication system. As the communication system, the simple ASK method, superheterodyne method, direct conversion method, or the like is assumed. The communication system using the superheterodyne method includes, for example, the antenna 1200, an amplifier 1201, a mixer 1202, a filter 1203, a mixer 1204, a converter 1205, a digital baseband modulator-demodulator 1206, and local oscillators 1207 and 1208. In the case of a receiver, a terahertz wave received via the antenna 1200 is converted into a signal of an intermediate frequency by the mixer 1202, and is then converted into a baseband signal by the mixer 1204, and an analog waveform is converted into a digital waveform by the converter 1205. After that, the digital waveform is demodulated in the baseband to obtain a communication signal. In the case of a transmitter, after a communication signal is modulated, the communication signal is converted from a digital waveform into an analog waveform by the converter 1205, is frequency-converted via the mixers 1204 and 1202, and is then output as a terahertz wave from the antenna 1200. The communication system using the direct conversion method includes the antenna 1200, an amplifier 1211, a mixer 1212, a modulator-demodulator 1213, and a local oscillator 1214. In the direct conversion method, the mixer 1212 directly converts the received terahertz wave into a baseband signal at the time of reception, and the mixer 1212 converts the baseband signal to be transmitted into a signal in a terahertz band at the time of transmission. The remaining components are similar to those in the superheterodyne method. The antenna apparatus according to each of the above-described embodiments can perform beamforming of a terahertz wave by electric control of a single chip. Therefore, it is possible to align radio waves between the transmitter and the receiver. By using the antenna apparatus of each of the above-described embodiments that can perform beamforming, in the communication system, it is possible to improve radio quality such as a signal-to-noise ratio, and transmit a large capacity of information in a wide coverage area at low cost.

### Other Embodiments

The embodiments of the present invention have been described above. However, the present invention is not limited to these embodiments and various modifications and changes can be made within the spirit and scope of the present invention.

For example, each of the above-described embodiments assumes that carriers are electrons. However, the present invention is not limited to this and holes may be used. Furthermore, the materials of the substrate and the dielectric are selected in accordance with an application purpose, and a semiconductor layer of silicon, gallium arsenide, indium arsenide, gallium phosphide, or the like, glass, ceramic, and a resin such as polytetrafluoroethylene or polyethylene terephthalate can be used.

In each of the above-described embodiments, a square patch antenna is used as a terahertz wave resonator but the shape of the resonator is not limited to this. For example, a resonator having a structure using a patch conductor having a polygonal shape such as a rectangular shape or triangular shape, a circular shape, an elliptical shape, or the like may be used.

The number of negative differential resistance elements integrated in an element is not limited to one and a resonator including a plurality of negative differential resistance elements may be used. The number of lines is not limited to one, and an arrangement including a plurality of lines may be used. By using the antenna apparatus described in each of the above embodiments, it is possible to oscillate and detect a terahertz wave.

In each of the above-described embodiments, a double-barrier RTD made of InGaAs/AlAs growing on the InP substrate has been described as an RTD. However, the present invention is not limited to the structure and material system, and even another combination of a structure and a material can provide an element of the present invention. For example, an RTD having a triple-barrier quantum well structure or an RTD having a multi-barrier quantum well structure of four or more barriers may be used. It can be said that the RTD includes bonding between different semiconductors, that is, heterojunction.

As the material of the RTD, each of the following combinations may be used.
GaAs/AlGaAs, GaAs/AlAs, and InGaAs/GaAs/AlAs formed on a GaAs substrate
InGaAs/InAlAs, InGaAs/AlAs, and InGaAs/AlGaAsSb formed on an InP substrate
InAs/AlAsSb and InAs/AlSb formed on an InAs substrate
SiGe/SiGe formed on an Si substrate

The above-described structure and material can appropriately be selected in accordance with a desired frequency and the like.

Furthermore, as the semiconductor layer 100, a Quantum Cascade Laser (QCL) having a semiconductor multilayer structure of several hundred to several thousand layers may be used. In this case, the semiconductor layer 100 is a semiconductor layer including the QCL structure. As the semiconductor layer 100, a negative resistance element such as a Gunn diode or IMPATT diode often used in the millimeter wave band may be used. As the semiconductor layer 100, a high frequency element such as a transistor with one terminal terminated may be used, and a heterojunction bipolar transistor (HBT), a compound semiconductor field effect transistor (FET), a high electron mobility transistor (HEMT), or the like is preferably used as the transistor. As the semiconductor layer 100, a negative differential resistance of the Josephson device using a superconductor layer may be used. As the semiconductor layer 100, an element including heterojunction may be used.

Any form of the relationship between the active antenna array 11 and the control circuit 165 may be possible. The active antenna array 11 includes a plurality of active antennas AA₁₁ to AAₘₙ, and the control circuit 165 includes a plurality of control elements AC₁₁ to ACₘₙ.

Each of the plurality of active antennas AA₁₁ to AAₘₙ may be controlled by a signal from each of the control elements AC₁₁ to ACₘₙ. That is, one control element may control one active antenna. It is possible to increase the degree of freedom of control of the antenna. Note that the control circuit 165 is not limited to the form including the plurality of control elements AC₁₁ to ACₘₙ, and need only be able to individually control the active antennas.

Furthermore, one control element may control a plurality of active antennas included in one group. In this case, the plurality of active antennas included in one group can correspond to each row or each column of the plurality of active antennas AA₁₁ to AAₘₙ arranged in a matrix. The plurality of active antennas included in one group can correspond to each region of a plurality of rows and a plurality of columns. Each group of the plurality of active antennas is operated, thereby facilitating control. In addition, the output can be increased for each group of the plurality of active antennas.

Furthermore, a plurality of control elements may control one active antenna. In this case, the degree of freedom of the operation can be increased. For example, each active antenna is controlled at each timing, or a plurality of active antennas are controlled at each timing.

If a complicated operation is performed, the above connection methods can arbitrarily be combined.

### Summary of Embodiments

At least some of the above embodiments can be summarized as follows.
(Item 1) An antenna apparatus comprising: a first substrate including an antenna array in which a plurality of active antennas each including an antenna and a semiconductor structure configured to generate or detect an electromagnetic wave are provided, and a wiring electrically connected to the plurality of active antennas; and a second substrate stacked on the first substrate and including a control circuit of the antenna array, wherein the first substrate and the second substrate are bonded at a bonding surface, the control circuit is electrically connected to the antenna array via the wiring, and the control circuit of the second substrate controls operations of the plurality of active antennas of the first substrate.
(Item 2) The apparatus according to Item 1, wherein the control circuit is electrically connected to the semiconductor structure via the wiring.
(Item 3) The apparatus according to Item 1 or 2, wherein the control circuit includes a plurality of control elements, and the plurality of control elements are connected to the plurality of active antennas in one-to-one correspondence.
(Item 4) The apparatus according to any one of Items 1 to 3, wherein the control circuit controls the plurality of active antennas by supplying signals with a predetermined voltage to the plurality of active antennas.
(Item 5) The apparatus according to any one of Items 1 to 4, wherein each of the plurality of active antennas includes a first conductor formed in a first layer of the first substrate, and a second conductor formed in a second layer arranged between the first layer and the bonding surface and having an area larger than an area of the first conductor.
(Item 6) The apparatus according to Item 5, wherein the second layer is provided between the bonding surface and the semiconductor structure.
(Item 7) The apparatus according to Item 6 or 5, wherein the wiring includes a first via configured to connect the first conductor and a third layer provided between the first layer and the second layer.
(Item 8) The apparatus according to Item 7, wherein the wiring includes a second via configured to connect the third layer and the control circuit through an opening of the second layer.
(Item 9) The apparatus according to Item 8, wherein the length of the first and second via is less than 1/10 of an electric length of the electromagnetic wave.
(Item 10) The apparatus according to Item 8 or 9, wherein the second via is arranged at a position not overlapping the first conductor in the stacking direction of the first substrates.
(Item 11) The apparatus according to any one of Items 5 to 10, further comprising a coupling line electrically connecting adjacent antennas, wherein the length of the coupling line is set based on the electric length of the electromagnetic wave in the coupling line.
(Item 12) The apparatus according to Item 11, wherein a third via electrically connecting the coupling line and the control circuit is arranged through an opening arranged at the second layer.
(Item 13) The apparatus according to Item 12, wherein the length of the third via is less than 1/10 of an electric length of the electromagnetic wave in the third via.
(Item 14) The apparatus according to any one of Items 11 to 13, further comprising a third layer is arranged between the first layer and the second layer, wherein the coupling line is connected to a wiring arranged on the third layer by a fourth via.
(Item 15) The apparatus according to Item 14, wherein the fourth via is arranged at a position which is different from the node of a standing wave of the electromagnetic wave in the coupling line.
(Item 16) The apparatus according to Item 14, wherein the fourth via is arranged at a position of the node of a standing wave of the electromagnetic wave in the coupling line.
(Item 17) The apparatus according to any one of Items 5 to 16, wherein the bonding surface arranged between the second layer and the control circuit.
(Item 18) The apparatus according to any one of Items 5 to 17, further comprising a fourth layer, arranged between the bonding surface and the control circuit, including a third conductor having an area larger than an area of the first conductor.
(Item 19) The apparatus according to Item 18, wherein the third conductor is a solid pattern.
(Item 20) The apparatus according to any one of Items 1 to 19, wherein the thickness of the first substrate is equal to or less than 1/10 of the wavelength of the electromagnetic wave.
(Item 21) The apparatus according to any one of Items 1 to 20, wherein the plurality of active antennas are arranged in a matrix in the antenna array.
(Item 22) The apparatus according to any one of Items 1 to 21, wherein the plurality of active antennas is arranged at a pitch equal to or smaller than the wavelength of the electromagnetic wave in the antenna array.
(Item 23) The apparatus according to any one of Items 1 to 22, wherein the antenna is a patch antenna.
(Item 24) The apparatus according to any one of Items 1 to 23, wherein the semiconductor structure includes a negative resistance element.
(Item 25) The apparatus according to Item 24, wherein the negative resistance element is a resonant tunneling diode.
(Item 26) The apparatus according to any one of Items 1 to 25, wherein the control circuit is a bias control circuit supplying a bias signal to the semiconductor structure.
(Item 27) The apparatus according to Item 11, wherein the control circuit is a phase control circuit for controlling a output phase of an electromagnetic wave to the antenna array.
(Item 28) The apparatus according to Item 27, wherein the phase control circuit is connected to the coupling line at a position of the node of a standing wave having a frequency of the electromagnetic wave and standing at the coupling line.
(Item 29) The apparatus according to Item 27, wherein the phase control circuit includes a impedance variable device changing the impedance of the coupling line in a frequency of the electromagnetic wave.
(Item 30) The apparatus according to any one of Items 1 to 29, wherein the control circuit includes an oscillator for outputting a frequency f/n, where n is a natural number and f is a frequency of the electromagnetic wave.
(Item 31) The apparatus according to any one of Items 1 to 30, wherein the plurality of active antennas includes a first active antenna for transmission and a second active antenna for reception.
(Item 32) The apparatus according to any one of Items 1 to 31, wherein the electromagnetic wave is an electromagnetic wave in the terahertz band.
(Item 33) A communication apparatus comprising: an antenna apparatus according to any one of Items 1 to 32; transmission means for emitting the electromagnetic wave; and reception means for detecting the electromagnetic wave.
(Item 34) An image capturing system comprising: an antenna apparatus according to any one of Items 1 to 32; transmission means for emitting the electromagnetic wave; and detection means for detecting the electromagnetic wave reflected by the object.

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD) (registered trademark)), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. An antenna apparatus comprising:
a first substrate including an antenna array in which a plurality of active antennas each including an antenna and a semiconductor structure configured to generate or detect an electromagnetic wave are provided, and a wiring electrically connected to the plurality of active antennas; and
a second substrate stacked on the first substrate and including a control circuit of the antenna array,
wherein the first substrate and the second substrate are bonded at a bonding surface,
the control circuit is electrically connected to the antenna array via the wiring, and
the control circuit of the second substrate controls oscillations of the plurality of active antennas of the first substrate.

2. The apparatus according to claim 1, wherein
the control circuit includes a plurality of control elements, and
the plurality of control elements are connected to the plurality of active antennas in one-to-one correspondence.

3. The apparatus according to claim 1, wherein each of the plurality of active antennas includes a first conductor formed in a first layer of the first substrate, and a second conductor formed in a second layer arranged between the first layer and the bonding surface and having an area larger than an area of the first conductor.

4. The apparatus according to claim 1, wherein the wiring includes a first via configured to connect the first conductor and a third layer provided between the first layer and the second layer.

5. A communication apparatus comprising:
an antenna apparatus according to claim 1;
transmission unit configured to emit an electromagnetic wave; and
reception unit configured to detect the electromagnetic wave.

6. An image capturing system comprising:
an antenna apparatus according to claim 1;
transmission unit configured to emit an electromagnetic wave to an object; and
detection unit configured to detect the electromagnetic wave reflected by the object.

7. An antenna apparatus comprising:
a first substrate including an antenna array in which a plurality of active antennas each including an antenna and a semiconductor structure configured to generate or detect an electromagnetic wave are provided, and a wiring electrically connected to the plurality of active antennas; and
a second substrate stacked on the first substrate and including a control circuit of the antenna array,
wherein the first substrate and the second substrate are bonded at a bonding surface,
the control circuit is electrically connected to the antenna array via the wiring, and
the control circuit of the second substrate controls the emission and detection of the electromagnetic wave via the plurality of active antennas of the first substrate.

8. The apparatus according to claim 7, wherein
the control circuit includes a plurality of control elements, and
the plurality of control elements are connected to the plurality of active antennas in one-to-one correspondence.

9. The apparatus according to claim 7, wherein each of the plurality of active antennas includes a first conductor formed in a first layer of the first substrate, and a second conductor formed in a second layer arranged between the first layer and the bonding surface and having an area larger than an area of the first conductor.

10. The apparatus according to claim 7, wherein the wiring includes a first via configured to connect the first conductor and a third layer provided between the first layer and the second layer.

11. A communication apparatus comprising:
an antenna apparatus according to claim 7;
transmission unit configured to emit an electromagnetic wave; and
reception unit configured to detect the electromagnetic wave.

12. An image capturing system comprising:
an antenna apparatus according to claim 7;
transmission unit configured to emit an electromagnetic wave to an object; and
detection unit configured to detect the electromagnetic wave reflected by the object.

13. An antenna apparatus comprising:
a first substrate including an antenna array in which a plurality of active antennas each including an antenna and a semiconductor structure configured to generate or detect an electromagnetic wave are provided, and a wiring electrically connected to the plurality of active antennas; and
a second substrate stacked on the first substrate and including a control circuit of the antenna array,
wherein the first substrate and the second substrate are bonded at a first bonding surface,
the control circuit is electrically connected to the antenna array via the wiring,
the control circuit of the second substrate controls operations of the plurality of active antennas of the first substrate, and
the first substrate contains a compound semiconductor to which a different compound is bonded by a second bonding surface.

14. The apparatus according to claim 13, wherein the first bonding surface and the second bonding surface are parallel to each other.

15. The apparatus according to claim 13, wherein each of the plurality of active antennas includes a first conductor formed in a first layer of the first substrate, and a second conductor formed in a second layer arranged between the first layer and the second bonding surface and having an area larger than an area of the first conductor.

16. The apparatus according to claim 13, wherein the wiring includes a first via configured to connect the first conductor and a third layer provided between the first layer and the second layer.

17. The apparatus according to claim 13, wherein
the compound semiconductor includes a first electrode electrically connected to the first conductor, and a second electrode electrically connected to the second conductor, and
the first conductor and the second conductor face each other.

18. A communication apparatus comprising:
an antenna apparatus according to claim 13;
transmission unit configured to emit an electromagnetic wave; and
reception unit configured to detect the electromagnetic wave.

19. An image capturing system comprising:
an antenna apparatus according to claim 13;
transmission unit configured to emit an electromagnetic wave to an object; and
detection unit configured to detect the electromagnetic wave reflected by the object.
